(19) United States
(12) Patent Application Publication
(10) Pub. No.: US 2017/0323829 A1
(43) Pub. Date: Nov. 9, 2017

(54) INTEGRATED CIRCUIT PACKAGE HAVING I-SHAPED INTERCONNECT

(71) Applicant: Twisden Ltd., TORTOLA (VG)

(72) Inventors: Loke Chew Low, TORTOLA (VG); Linhui Yuan, TORTOLA (VG)

(21) Appl. No.: 15/475,956

(22) Filed: Mar. 31, 2017

(30) Foreign Application Priority Data
Mar. 31, 2016 (MY) PI 2016701181

(51) Int. Cl. H01L 21/82; H01L 23/498; H01L 21/762; H01L 21/74; H01L 21/71; H01L 23/522; H01L 21/311

(52) U.S. Cl. CPC H01L 21/82; H01L 23/522; H01L 23/49822; H01L 21/311; H01L 21/743; H01L 21/71; H01L 21/762

(57) ABSTRACT

An integrated circuit packaging is described and includes a plurality of electrical circuits developed using a first patterned conductive layer on a base, wherein the electrical circuit is formed by using a masking material, and a stud conductive layer disposed on at least one side of the first patterned conductive layer developed by a second layer photo-resist material on the masking material, in which the second layer photo-resist material includes a first line layer with a smaller exposed area than the surface of the conductive layer disposed on one side of the first patterned conductive layer and a second line layer with a larger exposed area than the first line layer disposed on the first layer, such that the exposed area forms an “I” shaped connection of the conductive layer and the stud conductive layer.

### CROSS-REFERENCE TO RELATED APPLICATION

The instant application claims priority to Malaysia Patent Application Serial No. PI 2016701181 filed Mar. 31, 2016, the entire specification of which is expressly incorporated herein by reference.

### FIELD OF THE INVENTION

The invention relates in general to an integrated circuit package and manufacturing method thereof, and more particularly to an integrated circuit package having an “I” shaped connection of the conductive layer and the stud conductive layers to form an interconnect.

### BACKGROUND OF THE INVENTION

Recently, there was an increase in the number of terminals and the narrowing of their pitches in the semiconductor or integrated circuit device which result from advancements in the performance of operations, the capability of performing multi tasks and the integration thereof, which results in the growing demands of the interconnecting substrate for packaging which carries the semiconductor device also attains a higher density in arrangement and interconnections.

The current interconnecting substrate for packaging in-use, which are made of build-up multi-layered substrate, a sort of multi-layered interconnecting substrate.

Glass epoxy print substrates which are used as the base core substrate, which build-up multi-layered substrate is fabricated by forming an epoxy resin layer on both surfaces of this glass epoxy print substrate. Then, forming via holes in these epoxy resin layers by means of photolithography or laser. After that, plating method and the photolithography with a combination of the electroless or electrolytic Cu, in which an interconnection layer and via conductors are formed such that the formation of build-up layered structure is archived.

However, the glass epoxy print substrate may cause a problem that the heat treatments performed in fabrication of the build-up multi-layered substrate may bring the glass epoxy print substrate to a poor condition and creating defects. Furthermore, the heat treatments carried out at the time of chip loading and solder reflow may cause the faulty connection and the distortion which affects the long-term reliability for the connection.

Moreover, the interconnecting substrate for packaging is mounted on an external board or apparatus, the stress is structurally centered on the interface between the external electrode terminal and the insulating layer, which tends to give rise to opening defects so that the satisfactory mounting reliability cannot be obtained.

### SUMMARY OF THE INVENTION

Therefore the purpose of overcoming the above problems, there have been proposed an integrated circuit package and manufacturing method thereof, and more particularly to an integrated circuit package having an “I” shaped connection of the conductive layer and the stud conductive layer to form an interconnect.

One aspect of the present invention provides a method of fabricating an integrated circuit packaging, comprising the steps of:

establishing a base;

developing a plurality of electrical circuits using a first patterned conductive layer on the base, wherein an electrical circuit is formed by using a masking material; and

developing a stud conductive layer, where the stud conductive layer is disposed on at least one side of the first patterned conductive layer by developing a second layer photo-resist material on the masking material, in which the second layer photo-resist material includes a first line layer with a smaller exposed area than the surface of the conductive layer disposed on one side of the first patterned conductive layer and a second line layer with a larger exposed area than the first line layer disposed on the first layer, such that the exposed area forms an “I” shaped connection of the conductive layer and the stud conductive layer.

A further aspect of the present invention provides a method of fabricating an integrated circuit packaging, comprising the steps of:

removing the masking material and second layer photo-resist material; developing an encapsulating material from epoxy molding or epoxy laminate on the base and exposed area of the stud conductive layer;

grinding the surface area of the encapsulating material to level the surface of the stud conductive layer and the encapsulating material to form a flattened surface area;

developing third photo-resist materials on the flat surface area of the surface of the stud conductive layer and the encapsulating material; and

developing an opening on the patterned third photo-resist materials located at bottom portion of the base for etching selectively the base to form at least an internal opening and at least a positioning opening, wherein the internal opening corresponds with an inside area of the first patterned conductive layer, and the positioning opening corresponds with an outside area of the first patterned conductive layer.

Further, the method of fabricating an integrated circuit packaging comprises the steps of:

developing an interconnect on at least one side of the patterned conductive layer.

Preferably, the first patterned conductive layer and the second patterned conductive layer is disposed within the first patterned conductive layer, in which the other side of the first patterned conductive layer is located at the same plane with the second side of the second patterned conductive layer.

Preferably, the thickness of the first patterned conductive layer reduced by trimming at least one surface of the first patterned conductive layer.

Further, the surface of the first patterned conductive layer is trimmed by using chemical process or mechanical grinding process or laser trimming process or plasma treatment or any combination thereof.

Preferably, the masking material is a mask set or photolithography material or masked pattern or any combination thereof.

Preferably, the base is completely removed.

Preferably, the base is selectively removed to form at least an internal opening and at least a positioning opening of the first patterned conductive layer area, wherein the internal opening corresponds with an inside area of the first patterned conductive layer, and the positioning opening corresponds with an outside area of the first patterned conductive layer.

Preferably, the positioning opening is formed using a positioning mark or half-etched indentation or patterns on the base.

Preferably, the base is a charge carrier.

Preferably, the step of removing the base further comprises the steps of:

etching the base by using the third layer photo-resist material; and

removing the third layer photo-resist material.

Further, the step of etching the base comprises the steps of:

etching part of the first patterned conductive layer so that the surface of the etched first patterned conductive layer and the surface of the etched first patterned conductive layer is not located at the same plane.

Preferably, the masking material has at least a first opening and at least a second opening, the first opening is corresponding with the inside area of the first patterned conductive layer, and the second opening is corresponding with the outside area of the first patterned conductive layer.

Another aspect of the present invention provides an integrated circuit packaging, comprising:

a plurality of electrical circuits developed using a first patterned conductive layer on the base, wherein the electrical circuit formed by using a masking material; and

a stud conductive layer disposed on at least one side of the first patterned conductive layer developed by a second layer photo-resist material on the masking material, in which the second layer photo-resist material having a first line layer with a smaller exposed area than the surface of the conductive layer disposed on one side of the first patterned conductive layer and a second line layer with a larger exposed area than the first line layer disposed on the first layer, such that the exposed area forms an “I” shaped connection of the conductive layer and the stud conductive layer.

A further aspect of the present invention provides an integrated circuit packaging comprising:

an epoxy molding or laminate layer developed on the base and exposed area of the stud conductive layer as an encapsulating layer of material;

a third photo-resist materials developed on the surface area of the surface of the stud conductive layer encapsulating material; and

an opening on the patterned third photo-resist materials located at bottom portion of the base developed for etching selectively the base to form at least an internal opening and at least a positioning opening, wherein the internal opening corresponds with an inside area of the first patterned conductive layer, and the positioning opening corresponds with an outside area of the first patterned conductive layer.

Further, the integrated circuit packaging may include an interconnect on at least one side of the patterned conductive layer.

Preferably, the first patterned conductive layer has at least one trimmed surface.

Preferably, the trimmed surface of the first patterned conductive layer is trimmed by using chemical process, mechanical grinding process, laser trimming process, plasma etching or any combination thereof.

Preferably, the masking material is a mask set, photolithography material, masked pattern or any combination thereof.

Preferably, the base is selectively removed to form at least an internal opening and at least a positioning opening of the first patterned conductive layer exposed area.

Preferably, the base is selectively removed to form at least an internal opening and at least a positioning opening of the first patterned conductive layer exposed area, wherein the internal opening corresponds with an inside area of the first patterned conductive layer, and the positioning opening corresponds with an outside area of the first patterned conductive layer.

Preferably, the first patterned conductive layer and the second patterned conductive layer are disposed within the first patterned conductive layer, in which the other side of the first patterned conductive layer is located at the same plane with the second side of the second patterned conductive layer.

Preferably, the first patterned conductive layer is exposed to form at least an internal opening and at least a positioning opening by a selectively removing the base.

Preferably, the base is selectively removed to form at least an internal opening and at least a positioning opening, wherein the internal opening corresponds with an inside area of the first patterned conductive layer, and the positioning opening corresponds with an outside area of the first patterned conductive layer.

Further, the positioning opening has a positioning mark, half-etched indentation, full-etched indentation patterns or any combination thereof on any one of the dielectric layer.

Preferably, the base is a charge carrier.

Preferably, the base etched using the masking material as a mask.

Preferably, the first patterned conductive layer is encapsulated.

Preferably, the interconnect is a metal finishing or organic finishing or any combination thereof.

The present invention consists of features and a combination of parts hereinafter fully described and illustrated in the accompanying drawings, it being understood that various changes in the details may be made without departing from the scope of the invention or sacrificing any of the advantages of the present invention.

### BRIEF DESCRIPTION OF THE DRAWINGS

FIG. 1 illustrates an integrated circuit package according to at least one embodiment of the invention.

FIG. 2 illustrates layers of photo-resist materials are developed on a base, in which the layers are then developed or formed as patterned layers of photo-resist materials.

FIG. 3 illustrates development of an electrically conductive layer within the removed or etched part of the layers of photo-resist materials.

FIG. 4 illustrates the layers of photo-resist materials being removed, leaving an electrically conductive layer, wherein the first conductive layer can be used as electrical circuits or electrical routing.

FIG. 5 illustrates a second layer photo-resist material disposed on the surface of the first electrically conductive layer.

FIG. 6 illustrates a cavity developed on a patterned second layer photo-resist material.

FIG. 7 illustrates a stud conductive layer developed or disposed in the cavity.

FIG. 8 illustrates the remaining first photo-resist materials and second layer photo-resist material being removed or stripped, leaving a stud conductive layer disposed above the electrically conductive layer along the base.

FIG. 9 illustrates an epoxy or polymide process being developed or disposed on the base and exposed area of the stud conductive layer.

FIG. 10 illustrates, on the surface of the disposed epoxy molding compound, there is performed a grinding or polishing or trimming process known as surface grinding by either mechanical wheel grinding or chemical etching process or laser trimming.

FIG. 11 illustrates a fifth layer photo-resist material disposed on the surface of the surface of the stud conductive layer and bottom portion of the base.

FIG. 12 illustrates an opening that is developed on the patterned fifth layer photo-resist material located at bottom portion of the base, wherein it is developed by using an Ultra Violet (UV) exposure process or similar developer processes, in which the unexposed zone will be removed by using developer processes.

FIG. 13 illustrates that at least one part of the base can be removed, such that the area of the first patterned conductive layer is exposed to form at least an internal opening and at least a positioning opening.

FIG. 14 illustrates that at least one part of the first patterned conductive layer can be removed, such that the area of the first patterned conductive layer is exposed to form at least an internal opening or positioning opening.

### DETAILED DESCRIPTION OF THE INVENTION

To further clarify various aspects of some embodiments of the present invention, a more particular description of the invention will be rendered by references to specific embodiments thereof, which are illustrated in the appended drawings. It is appreciated that these drawings depict only typical embodiments of the invention and are therefore not to be considered limiting of its scope. The invention will be described and explained with additional specificity and detail through the accompanying drawings in which:

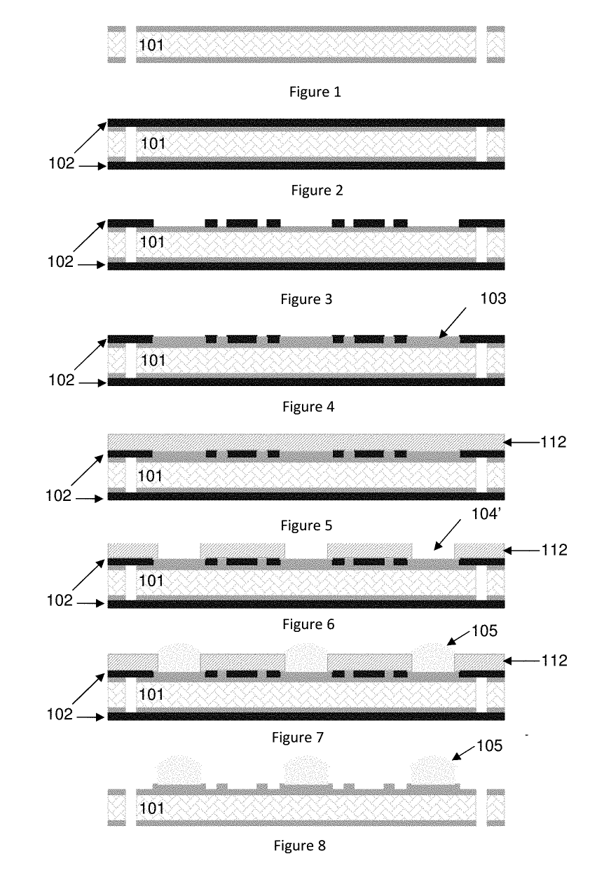

FIGS. 1-14 are detailed process flowcharts of manufacturing and connecting for an integrated circuit package, according to a first embodiment of the invention.

FIG. 1 illustrates an integrated circuit package according to at least one embodiment of the invention. Firstly, a carrier or base (101) is established or developed, wherein the base (101) is a steel material or copper or conductive material such as charge carrier. Preferably, the carbon steel or steel having thickness in the range of 0.005-0.500 mm, wherein the plated conductive layer having thickness in the range of 3-120 μm.

Then, FIG. 2 illustrates layers of photo-resist materials (102) are developed on the base (101), in which the layers are then developed or formed as patterned layers of photo-resist materials (102). Alternatively, the layers of photo-resist materials (102) are also formed on both surfaces of the carrier or base (101), bottom part and top part. The purpose of photo-resist materials (102) on the top portion is to create a masking for circuit patterning. However, the photo-resist materials (102) on the bottom portion are to avoid unnecessary buildup of plating material to avoid wastage of the plating material. This photo-resist material (102) has to on the bottom portion of the carrier or base (101) until demasking process. This process is also known as dry film laminating process by using a dry film laminator process, in which the dry film preferably has a thickness in the range of 5-100 μm.

FIG. 3 illustrates development of an electrically conductive layer (103) within the removed or etched part of the layers of photo-resist materials (102). The electrically conductive layer (103) developed by using electroplating method. Thereafter, the layers of photo-resist materials (102) will be removed, leaving the electrically conductive layer (103) wherein the first conductive layer can be used as electrical circuits or electrical routing as illustrated in FIG. 4. The layers of photo-resist materials (102) on the bottom part of the carrier or base (101) will still remain. Preferably, the layers of photo-resist materials are removed by Ultra Violet (UV) exposure process, in which the unexposed zone will be removed by developer process. Preferably, the development process of the electrically conductive layer (103) is also known as process of tracing conductive plating by using copper plating line, in which the conductive trace having thickness in the range of 5˜100 μm.

Then, the electrically conductive layer (103) is develop into a plurality of electrical circuits, which are electrically isolated and used as a package trace layout unit or electrical circuits unit, wherein the electrical circuits unit will be electrically connected to each other. This formation has same pattern to the integrated circuit that are ready for packaging.

FIG. 5 illustrates a second layer photo-resist material (112) disposed on the surface of the first electrically conductive layer (103′), and a cavity (104′) is developed on the patterned second layer photo-resist material (112) as shown in FIG. 6. Preferably, the second layer photo-resist material (112) or second dry film laminate with a dry film laminator has a thickness in the range of 5˜150 μm.

Preferably, the second layer photo-resist material (112) is form from two layers photo resist material, in which the first layer is disposed on the first electrically conductive layer (103′) and a first cavity is developed on the first layer, thereafter a second layer of the second layer photo-resist material (112) is disposed on the first layer to form a second cavity having larger opening from the first cavity, where the first and second cavity are disposed perpendicularly or inline.

Then stud conductive layer (105) is developed or disposed in the cavity (104′) as shown in FIG. 7, wherein the stud conductive layer (105) is developed by way of electroplating. Preferably, the stud conductive layer (105) and the first electrically conductive layer (103′) forms an “I” shape conductive layer or interconnection developed by plating line process.

Then the remaining first photo-resist materials (102) and second layer photo-resist material (112) will be removed or stripped, leaving the stud conductive layer (105) disposed above the electrically conductive layer (103) along the base (101) as illustrated in FIG. 8. Preferably, this process is known as the process of dry film stripping process.

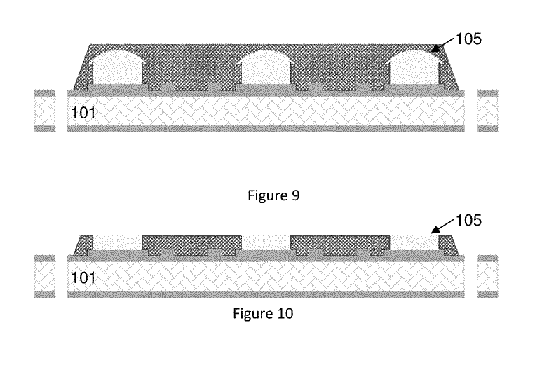

Then epoxy or polymide process is developed or disposed on the base (101) and exposed area of the stud conductive layer (105) as illustrated in FIG. 9. This process is known as an encapsulation process by using an epoxy or polymide compound. Preferably, by molding or laminate or curing process. Thereafter, on the surface of the disposed epoxy molding compound is performed a grinding or polishing or trimming process known as surface grinding by either mechanical wheel grinding or chemical etching process or laser trimming process as illustrated in FIG. 10. Preferably grinding or polishing or trimming process has a thickness in the control range of 5˜400 um. The surface grinding will flatten the surface of the stud conductive layer (105) and the disposed epoxy molding compound or polymide laminate to form a flattened surface area, in which if the stud conductive layer (105) having a curved angle on the top portion will be flatten by grinding or polishing the curved angle portion.

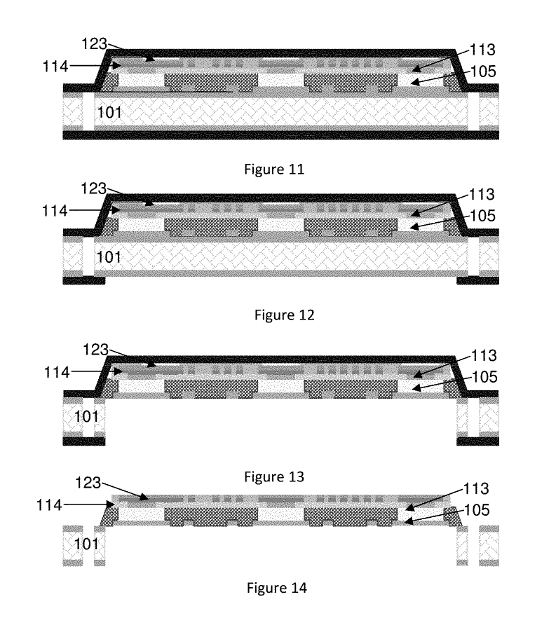

FIG. 11 illustrates a fifth layer photo-resist material disposed on the surface of the surface of the stud conductive layer (105) and bottom portion of the base (101). Preferably, the process is known as a window etching dry film laminate process with dry film laminator, wherein the dry film has a thickness in the range of 5˜120 μm. Then, an opening is developed on the patterned fifth layer photo-resist material located at bottom portion of the base (101), wherein its developed by using Ultra Violet (UV) exposure process or similar developer processes, in which the unexposed zone will be removed by using developer processes as shown in FIG. 12.

Thereafter, the base (101) can be removed fully or selectively to form at least an internal opening and at least a positioning opening, wherein the internal opening corresponds with an inside area of the first patterned conductive layer (103) and the positioning opening corresponds with an outside area of the first patterned conductive layer (103). The base (101) also can be removed, as well as at least one part of the first patterned conductive layer (103), such that the area of the first patterned conductive layer (103) is exposed to form at least an internal opening (107) and at least a positioning opening (107), as illustrated in FIGS. 13 and 14, respectively.

The present invention may be embodied in other specific forms without departing from its essential characteristics. The described embodiments are to be considered in all respects only as illustrative and not restrictive. The scope of the invention is, therefore indicated by the appended claims rather than by the foregoing description. All changes, which come within the meaning and range of equivalency of the claims, are to be embraced within their scope.

What is claimed is:

1. A method of fabricating an integrated circuit packaging, comprising the steps of:
establishing a base;
developing a plurality of electrical circuits using a first patterned conductive layer on the base, wherein an electrical circuit is formed by using a masking material; and
developing a stud conductive layer, where the stud conductive layer is disposed on at least one side of the first patterned conductive layer by developing a second layer photo-resist material on the masking material, in which the second layer photo-resist material includes a first line layer with a smaller exposed area than the surface of the conductive layer disposed on one side of the first patterned conductive layer and second line layer with a larger exposed area than the first line layer disposed on the first layer, such that the exposed area forms an “I” shaped connection of the conductive layer and the stud conductive layer.

2. The method of fabricating an integrated circuit packaging according to claim 1, further comprising the steps of:
removing the masking material and second layer photo-resist material;
developing an encapsulating material from epoxy or polyimide compound on the base and exposed area of the stud conductive layer;
grinding the surface area of the encapsulating material to level the surface of the stud conductive layer and the encapsulating material to form a flattened surface area;
developing third photo-resist materials on the flat surface area of the surface of the stud conductive layer and the encapsulating material; and
developing an opening on the patterned third photo-resist materials located at bottom portion of the base for etching selectively the base to form at least an internal opening and at least a positioning opening, wherein the internal opening corresponds with an inside area of the first patterned conductive layer, and the positioning opening corresponds with an outside area of the first patterned conductive layer.

3. The method of fabricating an integrated circuit packaging according to claim 1, further comprising the steps of:
developing an interconnect on at least one side of the patterned conductive layer.

4. The method of fabricating an integrated circuit packaging according to claim 1, wherein the first patterned conductive layer and the second patterned conductive layer are disposed within the first patterned conductive layer, in which the other side of the first patterned conductive layer is located at the same plane with the second side of the second patterned conductive layer.

5. The method of fabricating an integrated circuit packaging according to claim 3, wherein the thickness of the first patterned conductive layer reduced by trimming or grinding or polishing at least one surface of the first patterned conductive layer.

6. The method of fabricating an integrated circuit packaging according to claim 1, wherein the surface of the first patterned conductive layer is trimmed by using chemical process or mechanical grinding process or laser trimming process or plasma treatment or any combination thereof.

7. The method of fabricating an integrated circuit packaging according to claim 1, wherein the masking material is a mask set or photolithography material or masked pattern or any combination thereof.

8. The method of fabricating an integrated circuit packaging according to claim 1, wherein the base is completely removed.

9. The method of fabricating an integrated circuit packaging according to claim 1, wherein the base is selectively removed to form at least an internal opening and at least a positioning opening of the first patterned conductive layer area, wherein the internal opening corresponds with an inside area of the first patterned conductive layer, and the positioning opening corresponds with an outside area of the first patterned conductive layer.

10. The method of fabricating an integrated circuit packaging according to claim 1, wherein positioning opening is formed using a positioning mark or half-etched or full-etched indentation or patterns on the base.

11. The method of fabricating an integrated circuit packaging according to claim 1, wherein the base is a charge carrier.

12. The method of fabricating an integrated circuit packaging according to claim 1, wherein the step of removing the base further comprises the steps of:
etching the base by using the third layer photo-resist material; and
removing the third layer photo-resist material.

13. The method of fabricating an integrated circuit packaging according to claim 12, wherein the step of etching the base further comprising steps of:
etching part of the first patterned conductive layer so that the surface of the etched first patterned conductive layer and the surface of the etched first patterned conductive layer are not located at the same plane.

14. The method of fabricating an integrated circuit packaging according to claim 1, wherein the masking material has at least a first opening and at least a second opening, the first opening is corresponding with the inside area of the first patterned conductive layer, and the second opening is corresponding with the outside area of the first patterned conductive layer.

15. An integrated circuit packaging, comprising:
a plurality of electrical circuits developed using a first patterned conductive layer on a base, wherein an electrical circuit is formed by using a masking material; and
a stud conductive layer disposed on at least one side of the first patterned conductive layer developed by a second layer photo-resist material on the masking material, in which the second layer photo-resist material includes a first line layer with a smaller exposed area than the surface of the conductive layer disposed on one side of the first patterned conductive layer and a second line layer with a larger exposed area than the first line layer disposed on the first layer, such that the exposed area forms an “I” shaped connection of the conductive layer and the stud conductive layer.

16. The integrated circuit packaging according to claim 15, further comprising:
an epoxy or polyimide compound developed on the base and exposed area of the stud conductive layer as an encapsulating layer of material;
a third photo-resist materials developed on the surface area of the surface of the stud conductive layer encapsulating material; and
an opening on the patterned third photo-resist materials located at bottom portion of the base developed for etching selectively the base to form at least an internal opening and at least a positioning opening, wherein the internal opening corresponds with an inside area of the first patterned conductive layer, and the positioning opening corresponds with an outside area of the first patterned conductive layer.

17. The integrated circuit packaging according to claim 16, further includes an interconnect on at least one side of the patterned conductive layer.

18. The integrated circuit packaging according to claim 16, wherein the first patterned conductive layer has at least one trimmed surface.

19. The integrated circuit packaging according to claim 18, wherein the trimmed surface of the first patterned conductive layer is trimmed by using chemical process, mechanical grinding process, laser trimming process, plasma etching or any combination thereof.

20. The integrated circuit packaging according to claim 16, wherein the masking material is a mask set, photolithography material, masked pattern or any combination thereof.

21. The integrated circuit packaging according to claim 16, wherein the base is selectively removed to form at least an internal opening and at least a positioning opening of the first patterned conductive layer exposed area.

22. The integrated circuit packaging according to claim 16, wherein the base is selectively removed to form at least an internal opening and at least a positioning opening of the first patterned conductive layer exposed area, wherein the internal opening corresponds with an inside area of the first patterned conductive layer, and the positioning opening corresponds with an outside area of the first patterned conductive layer.

23. The integrated circuit packaging according to claim 16, wherein the first patterned conductive layer and the second patterned conductive layer are disposed within the first patterned conductive layer, in which the other side of the first patterned conductive layer is located at the same plane with the second side of the second patterned conductive layer.

24. The integrated circuit packaging according to claim 16, wherein the first patterned conductive layer is exposed to form at least an internal opening and at least a positioning opening by a selectively removing the base.

25. The integrated circuit packaging according to claim 16, wherein the base is selectively removed to form at least an internal opening and at least a positioning opening, wherein the internal opening corresponds with an inside area of the first patterned conductive layer, and the positioning opening corresponds with an outside area of the first patterned conductive layer.

26. The integrated circuit package according to claim 25, wherein the positioning opening has a positioning mark, half-etched indentation, full-etched indentation patterns or any combination thereof on any one of the dielectric layer.

27. The integrated circuit packaging according to claims 16, wherein the base is a charge carrier.

28. The integrated circuit packaging according to claim 16, wherein the base is etched using the masking material as a mask.

29. The integrated circuit packaging according to claim 16, wherein the first patterned conductive layer is encapsulated.

30. The integrated circuit packaging according to claim 17, wherein the interconnect is a metal finishing or organic finishing or any combination thereof.
